(19) United States
(12) Patent Application Publication
(10) Pub. No.: US 2007/0077690 A1
(43) Pub. Date: Apr. 5, 2007

(54) Semiconductor device with transistors and fabricating method therefor

(76) Inventors: Zing-Way Pei, Hsinchu (TW); Chen-Pang Kung, Hsinchu (TW)

Correspondence Address: RABIN & Berdo, PC, 1101 14TH STREET, NW, SUITE 500, WASHINGTON, DC, 20005, US

(21) Appl. No.: 11/363,928

(22) Filed: Mar. 1, 2006

(30) Foreign Application Priority Data
Sep. 30, 2005 (TW) 094134286

(51) Int. Cl. H01L 21/84; H01L 21/00; H01L 33/00; H01L 29/18

(52) U.S. Cl. 438/149; 438/151; 257/88

(57) ABSTRACT

A semiconductor device with transistors and a fabricating method therefore are provided. The electrodes of the transistors are formed on the same layer, and they are coupled to one another by a conductor layer. Therefore, the requirement for the vias in whole circuit is reduced, and the cost is decreased.

### BACKGROUND

1. Field of Invention

The invention relates to a semiconductor device and in particular to a semiconductor device with a plurality of transistors and a fabricating method therefor.

2. Related Art

In a logic circuit, an inverter functions as a basic component. Therefore, whether a circuit is composed of a complementary metal oxide semiconductor (CMOS) inverter, an n-type metal oxide semiconductor (NMOS) inverter, a p-type metal oxide semiconductor (PMOS) inverter or a resistive load inverter, the circuit needs interconnections for the source-to-gate (namely a buffer or source/drain electrode output is used as the input of next circuit level), the source electrode to source/drain electrodes, or the gate to gate (ex. inverter component). Vias are utilized by the conventional method for establishing interconnections of circuits.

A conventional process of establishing interconnection is described below.

In the related art, a photolithography and an oxygen plasma etching processes are used to patternize a polyvinyl pyrrolidone (PVP) film for forming a via to connect two interconnecting layers. Then, by an evaporation process or an inkjet printing process, a small molecular or polymer organic semiconductor material is used to patternize the place between the source electrode and the drain electrode in order to produce an organic transistor. (Please refer to H. Klauk, M. Halik, U. Zschieschang, F. Eder, G. Schmid, and C. Dehm, Pentacene organic transistors and ring oscillators on glass and on flexible polymeric substrates, Applied Physics Letters, Vol. 82, Issue 23, P4175-P4177, 9 Jun. 1996).

Another related art involves printing carbon ink on a place to be an interconnection portion in advance, and then completing the device. (Please refer to A. Knobloch, A. Manuelli, A. Bernds, and W. Clemens, Fully printed integrated circuits from solution processable polymers, Journal of Applied Physics, Vol. 96, Issue 4, P2289-P2291, 15 Aug. 2004).

Another related art involves disposing metal lines at two sides of the substrate then connecting them with vias. (Please refer to B. Crone, A. Dodabalapur, Y.-Y. Lin, R W Filas, Z. Bao, A. LaDuca, R. Sarpeshkar, H E Katz, W. Li, Large-scale complementary integrated circuits based on organic transistors, Nature, Vol. 403, P521-P523, 2000).

There is one another related art using a shadow mask pattern technique. (Please refer to P F Baude, D A Ender, M A Haase, T W Kelley, D V Muyres, and S D Theiss, Pentacene-based radio-frequency identification circuitry, Applied Physics Letters, Vol. 82, Issue 22, P3964-P3966, 2 Jun. 2003)

However, in a conventional process of organic electronics, vias are generally produced by a laser drill process, or produced by a photolithography or a plasma etching processes, which costs a lot of money and complicates the process. Therefore, using those kinds of techniques defeats the purpose of making the process easier and making the organic electronics cheaper.

### SUMMARY

An object of the invention is to provide a semiconductor device with transistors and a fabricating method therefor to reduce the number of vias in a circuit.

According to the invention, an embodiment of the method for fabricating a semiconductor device with transistors includes the steps of: providing a substrate; forming a first conductive layer on the substrate, where the first conductive layer includes a first electrode region and at least one second electrode region; the first electrode region electrically connects to one of the second electrode regions; forming a first semiconductor layer to cover the second electrode region; forming a dielectric layer to cover the first electrode region and the first semiconductor layer; forming a second semiconductor layer on the dielectric layer that corresponds to the first electrode region; and forming a second conductive layer that includes a third electrode region, which corresponds to the second electrode region, on the dielectric layer, and a fourth electrode region, which corresponds to the first electrode region, on the second semiconductor layer.

The invention provides another embodiment of the method for fabricating a semiconductor device with transistors, which includes the steps of: providing a substrate; forming a first conductive layer on the substrate, where the first conductive layer includes a first electrode region and one second electrode region; forming a first semiconductor layer to cover the second electrode region; forming a dielectric layer to cover the first electrode region and the first semiconductor layer; forming a second semiconductor layer on the dielectric layer that corresponds to the first electrode region; and forming a second conductive layer that includes a third electrode region, which corresponds to the second electrode region, on the dielectric layer, and forth electrode regions, which correspond to the first electrode region, on the second semiconductor layer, where the third electrode region electrically connects to one of the fourth electrode regions.

In addition, according to the methods above, a semiconductor device with the first electrode region electrically connecting to one of the second electrode regions, or a semiconductor device with a plurality of transistors having the third electrode region electrically connecting to the fourth electrode region can also be obtained.

### BRIEF DESCRIPTION OF THE DRAWINGS

The invention will become more fully understood from the detailed description given below, which is for illustration only and thus is not limitative of the invention, wherein:

FIGS. 1A to 1F show the cross section diagrams of an embodiment of a method for fabricating a semiconductor device according to the invention;

FIG. 2 is a top view of FIG.1B; and

FIG. 3 is a top view of FIG. 1F.

### DETAILED DESCRIPTION

The concept of the invention is to make the electrodes to be electrically connected may connect with one another on the same layer, and directly connect the two terminals connected to one another by a conductive layer. This dramatically reduces the number of vias used based on practical circumstances.

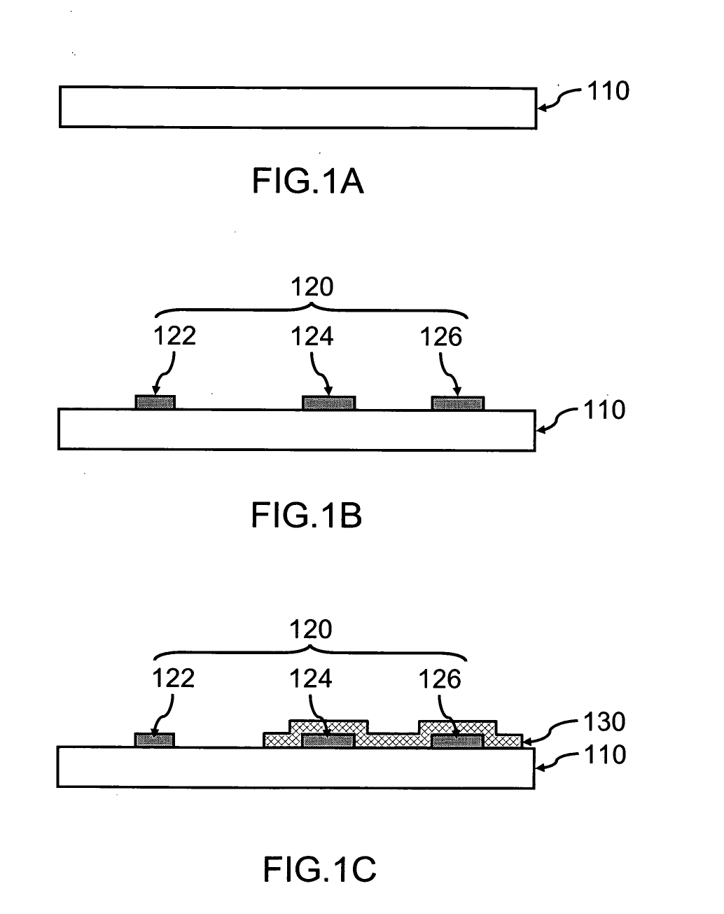

Please refer to FIGS. 1A to 1F, showing a flow chart of the fabricating method of the semiconductor device according to an embodiment of the invention. In FIG. 1A, a substrate 110 is provided.

The preferred material of the substrate is an isolating material, such as a polymer, a plastic or a glass. The material can be rigid or flexible and also can be a printing circuit board (PCB) material that includes an epoxy or a ceramic and has a silicon isolation layer or a silicon oxide isolation layer thereon.

Next, a first conductive layer 120 is formed on the substrate 110, where the first conductive layer 120 includes a first electrode region 122 (i.e. first electrode) and at lease one second electrode region 124 and 126 (i.e. second electrode), as shown in FIG. 1B.

The first conductive layer can be made of any kind of conductive material with a conductivity of about 10⁻² to 10⁶ S/cm. Here, the conductive material can be a high conductive material such as Au, Ag, Cu, Ni, Ti, Pt, Nd, or other high conductive metal compounds of composition of the above elements, a conductive polymer such as a polyaniline (PANI) or polyethylene dioxythiophene: polysterene sulfonic acid (PEDOT:PSS), or a conductive oxide such as indium tin oxide (ITO) or indium zin oxide (IZO). Except for choosing a high conductivity material, another factor for choosing a preferred material for the first conductive layer is how the material matches to the first semiconductor layer and the device.

As shown in FIG. 1C, a first semiconductor layer is formed to cover the second electrode regions 124 and 126.

A material for the first semiconductor layer can include an electron-hole transporting material (i.e. p-type semiconductor layer) or an electron transporting material (i.e. n-type semiconductor layer). Here, the electron-hole transporting material can be a pentacene, a poly (3-hexylthiophene) (P3HT), a p-type material such as a derivative of the above compounds, or a p-type material mixed with cathode materials. The cathode materials can be carbon nanotubes, Si nanowires, SiC/Si nanoneedles, SiCN nanorods, AlN nanoneedles, or other inorganic nanoneedles. The electron transporting material can be a copper hexadecafluorophthalocyanine (F16CuPc), a perylene-tetracarboxylic-diimide (PTCDI), a carbon sixty (C₆₀), an n-type material such as a derivative of the above compounds, or an n-type material mixed with cathode materials. The cathode materials can be carbon nanotubes, Si nanowires, SiC/Si nanoneedles, SiCN nanorods or AlN nanoneedles.

Then, a dielectric layer 140 is formed on the first electrode region 122 and the first semiconductor layer 130 as shown in FIG. 1D. In other words, a covered dielectric layer 140 can be grown thereon.

The dielectric constant of the dielectric layer is larger than 1. Also, a material for the dielectric layer can be a polymer isolating material such as a poly vinyl alcohol (PVA), a poly vinyl pyrrolidone (PVP), a polyacrylonitrile (PAN), a polystyrene (PS), a polymethylmethacrylate (PMMA) or a mixture of the compounds above, an inorganic material such as a SiO₂, SiN, Al₂O₃, TiO₂, HfO₂, ZrO₂ or Ta₂O₅, or a polymer isolating material or its mixture that is mixed with an inorganic material. The inorganic material can be SiO₂, SiN, Al₂O₃, TiO₂, HfO₂, ZrO₂ or Ta₂O₅. The choice for the preferred material of the dielectric layer depends on how it matches to the process as well as the current leakage extent of the material to the device.

A second semiconductor layer 150 is formed on the dielectric layer 140 corresponding to the first electrode region 122, as shown in FIG. 1E.

The material for the second semiconductor layer can include an electron-hole transporting material (i.e. p-type semiconductor layer) or an electron transporting material (i.e. n-type semiconductor layer). Here, the electron-hole transporting material can be a pentacene, a P3HT, a p-type material such as a derivative of the above compounds, or a p-type material mixed with cathode materials. The cathode materials can be carbon nanotubes, Si nanowires, SiC/Si nanoneedles, SiCN nanorods, AlN nanoneedles, or other inorganic nanoneedles. The electron transporting material can be a F16CuPc, a PTCDI, a C₆₀, an n-type material such as a derivative of the above compounds, or an n-type material mixed with cathode materials. The cathode materials can be carbon nanotubes, Si nanowires, SiC/Si nanoneedles, SiCN nanorods or AlN nanoneedles.

Finally, a second conductive layer 160 is formed. The second conductive layer 160 includes a third electrode region 162 (i.e. third electrode) and fourth electrode regions 164 and 166 (i.e. fourth electrode), as shown in FIG. 1F. Among them, the second conductive layer 160 can be made of any kind of conductive material, with a conductivity of about 10⁻² to 10⁶ S/cm. Here, the conductive material can be a high conductive material such as Au, Ag, Cu, Ni, Ti, Pt, Nd, a high conductive metal compound such as a composition of the above elements, a conductive polymer such as a PANI or a PEDOT:PSS, or conductive oxides such as ITO or IZO.

In order to clearly describe the invention, only two semiconductor devices are formed in this embodiment, including a third electrode region 162 located at the dielectric layer 140 at the middle of the area corresponding to the second electrode regions 124 and 126, and the fourth electrode regions 164 and 166 located at the second semiconductor layer 150 corresponding to the two side of the first electrode region 122.

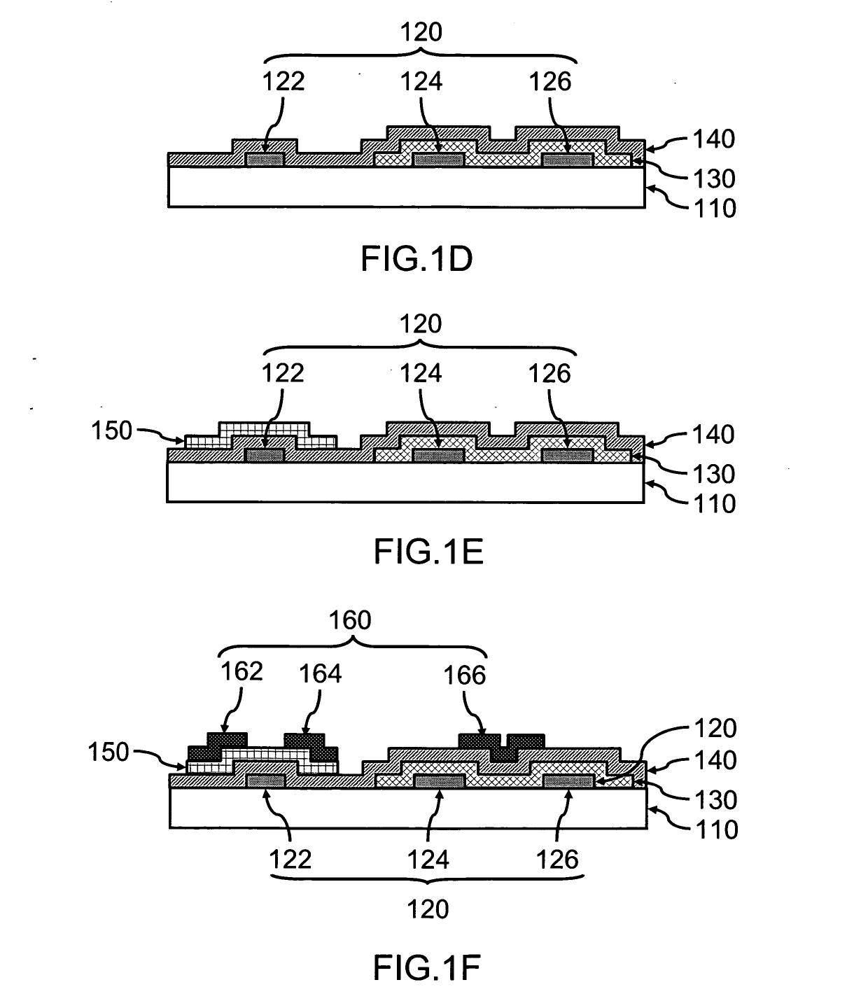

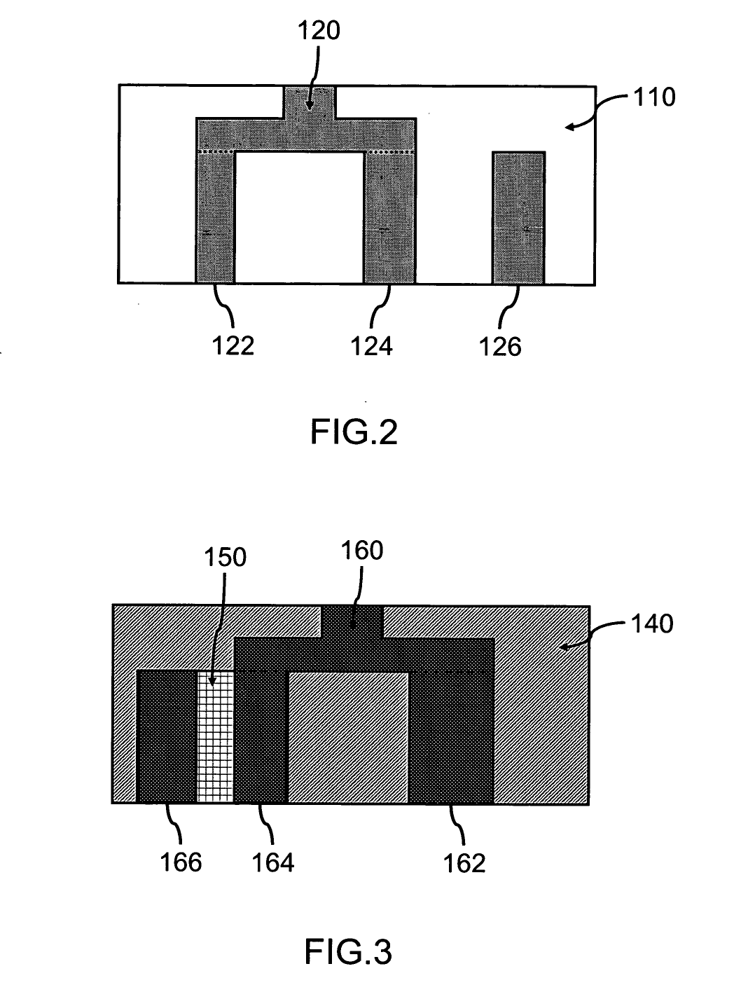

In this embodiment, the first electrode region 122 can be electrically connected to one of the second electrode regions 124 and 126 (shown in FIG. 2), or the third electrode region 162 can be electrically connected to one of the fourth electrode regions 164 and 166 (shown in FIG. 3) to electrically connect the two semiconductor devices. In other words, when the first electrode region 122 and the third electrode region 162 are used as gate electrodes, and the second electrode regions 124 and 126 and the fourth electrode regions 164 and 166 are used as source/drain electrodes, a new type of semiconductor device where two transistors have gate to source/drain electrode interconnection can be obtained.

Here, although the description above proceeds by the structure of gate to source/drain electrodes, similarly, two interconnecting semiconductor devices with structures of source electrode to gate, source electrode to source/drain electrodes or gate to gate can also be obtained by modifying the electrode regions of the conductive layers and the semiconductor layers.

Next, every layer (i.e. the first conductive layer, the first semiconductor layer, the dielectric layer, the second semiconductor layer and the second conductive layer) can be formed by depositing or coating and then patternizing processes according to requirements.

For example, by depositing or coating the conductive material and then patternizing it by a lithographic printing process according to requirements, the structures for the first conductive layer and the second conductive layer can be formed. Besides, other technologies also can be used for producing the same structure.

In addition, the semiconductor with two transistors described here is only for the purpose of clear description. The same concept can apply to a semiconductor with multiple transistors. In other words, forming the electrodes connecting the transistors on the same layer and using the conductive layers to connect the terminals can dramatically reduce the number of vias in a circuit and thus decrease the cost.

While the preferred embodiments of the invention have been set forth for the purpose of disclosure, modifications of the disclosed embodiments of the invention as well as other embodiments thereof may occur to those skilled in the art. Accordingly the appended claims are intended to cover all embodiments, which do not depart from the spirit and scope of the invention.

What is claimed is:

1. A method for fabricating a semiconductor device comprising:
providing a substrate;
forming a first conductive layer on the substrate wherein the first conductive layer includes:
a first electrode region; and
at least one second electrode region, wherein the first electrode region electrically connects to one of the second electrode regions;
forming a first semiconductor layer to cover the second electrode region;
forming a dielectric layer to cover the first electrode region and the first semiconductor layer;
forming a second semiconductor layer on the dielectric layer that corresponds to the first electrode region; and
forming a second conductive layer wherein the second conductive layer includes:
a third electrode region on the dielectric layer that corresponds to the second electrode region; and
at least one fourth electrode region on the second semiconductor layer that corresponds to the first electrode region.

2. The method according to claim 1 wherein the first electrode region and the third electrode region are used as gates respectively, and the second electrode region and the fourth electrode region are used as source/drain electrodes respectively.

3. The method according to claim 1 wherein the substrate includes an isolating material.

4. The method according to claim 1 wherein the first conductive layer and the second conductive layer have a conductivity of about 10⁻² to 10⁶ S/cm.

5. The method according to claim 1 wherein the first conductive layer and the second conductive layer include a material selected from the group consisted of a high conductive metal, a conductive polymer, and a conductive oxide.

6. The method according to claim 1 wherein the dielectric layer has a dielectric constant larger than 1.

7. The method according to claim 1 wherein the dielectric layer includes a material selected form the group consisting of a polymer isolating material, an inorganic material or compositions thereof.

8. The method according to claim 1 wherein the first and the second semiconductor layers include a material selected from the group consisting of an electron-hole transporting material and an electron transporting material.

9. A method for fabricating a semiconductor device comprising:
providing a substrate;
forming a first conductive layer on the substrate wherein the first conductive layer includes a first electrode region and at least one second electrode region;
forming a first semiconductor layer to cover the second electrode region;
forming a dielectric layer to cover the first electrode region and the first semiconductor layer;
forming a second semiconductor layer on the dielectric layer that corresponds to the first electrode region; and
forming a second conductive layer on the second conductive layer and the dielectric layer wherein the second conductive layer includes:
a third electrode region on the dielectric layer that corresponds to the second electrode region; and
at least one fourth electrode region on the second semiconductor layer that corresponds to the first electrode region wherein the third electrode region electrically connects to one of the fourth electrode region.

10. The method according to claim 9 wherein the first electrode region and the third electrode are used as gates respectively, and the second electrode and the fourth electrode are used as source/drain electrodes respectively.

11. The method according to claim 9 wherein the material of the substrate includes an isolating material.

12. The method according to claim 9 wherein the first conductive layer and the second conductive layer have a conductivity of about 10⁻² to 10⁶ S/cm.

13. The method according to claim 9 wherein the first conductive layer and the second conductive layer include a material selected from the group consisting of a high conductive metal, a conductive polymer, and a conductive oxide.

14. The method according to claim 9 wherein the dielectric layer has a dielectric constant larger than 1.

15. The method according to claim 9 wherein the dielectric layer include a material selected form the group consisting of a polymer isolating material, an inorganic material, or compositions thereof.

16. The method according to claim 9 wherein the first and the second semiconductor layers include a material selected from the group consisting of an electron-hole transporting material and an electron transporting material.

17. A semiconductor device comprising:
a substrate;
a first electrode on the substrate;
at least one second electrode on the substrate wherein one of the second electrodes electrically connects to the first electrode;
a first semiconductor layer covering the second electrode;
a dielectric layer covering the first electrode and the first semiconductor layer;
a second semiconductor layer on the dielectric layer that corresponds to the first electrode region;
a third electrode on the dielectric layer corresponding to the second electrode; and
at least one fourth electrode on the second semiconductor layer corresponding to the first electrode.

18. The device according to claim 17 wherein the first electrode region and the third electrode region are used as gates respectively, and the second electrode region and the fourth electrode region are used as source/drain electrodes respectively.

19. The device according to claim 17 wherein the material of the substrate includes an isolating material.

20. The device according to claim 17 wherein the first electrode, the second electrode, the third electrode, and the fourth electrode have a conductivity of about 10⁻² to 10⁶ S/cm.

21. The device according to claim 17 wherein the first electrode, the second electrode, the third electrode and the fourth electrode include a material selected from the group consisting of a high conductive metal, a conductive polymer and a conductive oxide.

22. The device according to claim 17 wherein the dielectric layer has a dielectric constant larger than 1.

23. The device according to claim 17 wherein the dielectric layer include a material selected form the group consisting of a polymer isolating material, an inorganic material, or compositions thereof.

24. The device according to claim 17 wherein the first and the second semiconductor layers include a material selected from the group consisting of an electron-hole transporting material and an electron transporting material.

25. A semiconductor device with a plurality of transistors comprising:
a substrate;
a first electrode on the substrate;
at least one second electrode on the substrate;
a first semiconductor layer covering the second electrode;
a dielectric layer covering the first electrode and the first semiconductor layer;
a second semiconductor layer on the dielectric layer that corresponds to the first electrode region;
a third electrode on the dielectric layer corresponding to the second electrode; and
at least one fourth electrode on the second semiconductor layer corresponding to the first electrode wherein the third electrode electrically connects to one of the fourth electrodes.

26. The device according to claim 25 wherein the first electrode and the third electrode are used as gates respectively, and the second electrode and the fourth electrode are used as source/drain electrodes respectively.

27. The device according to claim 25 wherein the material of the substrate includes an isolating material.

28. The device according to claim 25 wherein the first electrode, the second electrode, the third electrode, and the fourth electrode have a conductivity of about 10⁻² to 10⁶ S/cm.

29. The device according to claim 25 wherein the first electrode, the second electrode, the third electrode, and the fourth electrode include a material selected from the group consisting of a high conductive metal, a conductive polymer, and a conductive oxide.

30. The device according to claim 25 wherein the dielectric layer has a dielectric constant larger than 1.

31. The device according to claim 25 wherein the dielectric layer includes a material selected form the group consisting of a polymer isolating material, an inorganic material, or compositions thereof.

32. The device according to claim 25 wherein the first and the second semiconductor layers include a material selected from the group consisting of an electron-hole transporting material and an electron transporting material.
